(19) United States
(12) Patent Application Publication
(10) Pub. No.: US 2005/0126708 A1
(43) Pub. Date: Jun. 16, 2005

(54) Retaining ring with slurry transport grooves

(75) Inventors: Hung Chih Chen, Santa Clara, CA (US); Steven M. Zuniga, Soquel, CA (US)

Correspondence Address: PATENT COUNSEL;APPLIED MATERIALS, INC., Legal Affairs Department, P.O. BOX 450A, Santa Clara, CA, 95052, US

(73) Assignee: Applied Materials, Inc.

(21) Appl. No.: 10/732,966

(22) Filed: Dec. 10, 2003

(51) Int. Cl. H01L 21/306

(52) U.S. Cl. 156/345.14; 216/52

(57) ABSTRACT

A retaining ring for chemical mechanical polishing has a generally annular body with a top surface, a bottom surface, an inner diameter surface, and an outer diameter surface. The bottom surface includes a plurality of channels, each channel extending from the inner diameter surface to the outer diameter surface and having a rounded ceiling.

### BACKGROUND

The present invention relates generally to chemical mechanical polishing of substrates, and more particularly to a retaining ring for use in chemical mechanical polishing.

An integrated circuit is typically formed on a substrate by the sequential deposition of conductive, semiconductive or insulative layers on a silicon substrate. One fabrication step involves depositing a filler layer over a non-planar surface, and planarizing the filler layer until the non-planar surface is exposed. For example, a conductive filler layer can be deposited on a patterned insulative layer to fill the trenches or holes in the insulative layer. The filler layer is then polished until the raised pattern of the insulative layer is exposed. After planarization, the portions of the conductive layer remaining between the raised pattern of the insulative layer form vias, plugs and lines that provide conductive paths between thin film circuits on the substrate. In addition, planarization is needed to planarize the substrate surface for photolithography.

Chemical mechanical polishing (CMP) is one accepted method of planarization. This planarization method typically requires that the substrate be mounted on a carrier or polishing head of a CMP apparatus. The exposed surface of the substrate is placed against a rotating polishing disk pad or belt pad. The polishing pad can be either a “standard” pad or a fixed-abrasive pad. A standard pad has a durable roughened surface, whereas a fixed-abrasive pad has abrasive particles held in a containment media. The carrier head provides a controllable load on the substrate to push it against the polishing pad. A polishing slurry, including at least one chemically-reactive agent, and abrasive particles if a standard pad is used, is supplied to the surface of the polishing pad.

### SUMMARY

In one aspect, the invention is directed to a retaining ring. The retaining ring has a generally annular body with a top surface, a bottom surface, an inner diameter surface, and an outer diameter surface. The bottom surface includes a plurality of channels, each channel extending from the inner diameter surface to the outer diameter surface and having a rounded ceiling.

Implementations of the invention may include one or more of the following features. The rounded ceiling may have a semi-circular cross-section, and the semi-circular cross-section may have a diameter about equal to a width of the channel. The rounded ceiling may have a flat portion. The rounded ceiling may be rounded at an intersection of the flat portion and vertical side-walls of the channel. Each channel may include substantially vertical side-walls. The plurality of channels may have substantially uniform depth. The plurality of channels may be oriented at an angle, e.g., between 30° and 60°, relative to a radial segment extending through the center of the retaining ring. The outer diameter surface may includes a ledge. The outer diameter surface may include a first portion adjacent the bottom surface that has an outer diameter less than a second portion adjacent the top surface. Each channel may includes substantially vertical side-walls, and the side walls may extend to substantially the same depth as the ledge. The annular body may include wearable material. The annular body may include an upper portion and a lower portion, and the upper portion may be more rigid than the lower portion. The channels may be formed in the lower portion. A plurality of passages may extend through the upper portion from the inner diameter surface to the outer diameter surface. The plurality of channel may be distributed at substantially equal angular intervals around the retaining ring.

In another aspect, the invention is directed to a carrier head. The carrier head has a substrate receiving surface and a generally annular retaining ring surrounding the substrate receiving surface. The retaining ring has a top surface, a bottom surface, an inner diameter surface, and an outer diameter surface. The bottom surface includes a plurality of channels, each channel extending from the inner diameter surface to the outer diameter surface and having a rounded ceiling.

In another aspect, the invention is directed to a method of polishing. The method includes creating relative motion between a substrate and a polishing surface, restraining the substrate with retaining ring, and supplying a polishing liquid to the polishing surface. The retaining ring has a top surface, a bottom surface, an inner diameter surface, and an outer diameter surface, and the bottom surface includes a plurality of channels, each channel extending from the inner diameter surface to the outer diameter surface and having a rounded ceiling. The polishing liquid flows through the channels and beneath the retaining ring to the substrate.

One potential advantage of the invention is that because the grooves on the bottom surface of the retaining ring lack sharp corners, slurry may be less likely to accumulate in the grooves. Thus, the slurry may be less likely to coagulate or dry and form large particles, and therefore defects such as scratching may be reduced.

Another potential advantage of the invention is that if a portion of the grooves at the bottom surface of the retaining ring have vertical side walls, the slurry-transport performance of the retaining ring may remain relatively stable as the retaining ring wears.

### BRIEF DESCRIPTION OF THE DRAWINGS

FIG. 1 is a schematic perspective view of a retaining ring according to the present invention.

FIG. 2 is a schematic planar bottom view of the retaining ring of FIG. 1.

FIG. 3 is a cross-sectional view taken along line 3-3 in FIG. 2.

FIG. 4 is a cross-sectional view taken along line 4-4 in FIG. 2.

FIG. 5 is a cross-sectional view of another implementation of the retaining ring.

### DETAILED DESCRIPTION

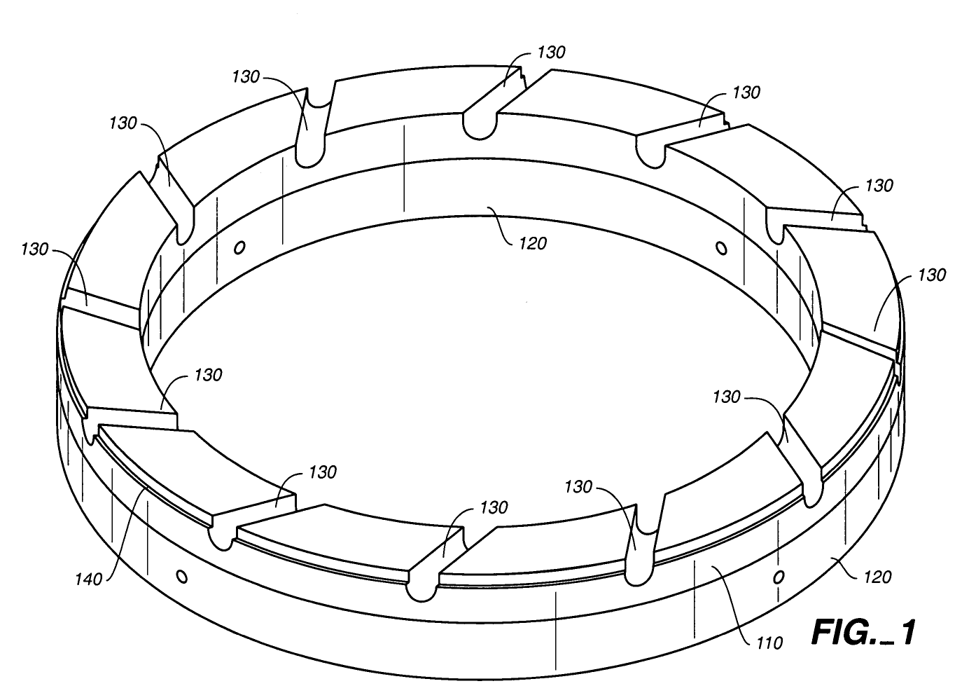

Referring to FIG. 1, a retaining ring 100 is a generally an annular ring that can be secured to a carrier head of a CMP apparatus. A suitable CMP apparatus is described in U.S. Pat. No. 5,738,574 and a suitable carrier heads are described in U.S. Pat. No. 6,251,215, and U.S. patent application Ser. No. 09/712,389, filed Nov. 13, 2000, the entire disclosures of which are incorporated herein by reference. The retaining ring 100 fits into a loadcup for positioning, centering, and holding the substrate at a transfer station of the CMP apparatus. A suitable loadcup is described in patent application Ser. No. 09/414,907, filed Oct. 8, 1999, entitled EDGE CONTACT LOAD CUP (EP Publication No. 1061558), and assigned to the assignee of the present invention, the entire disclosure of which is hereby incorporated.

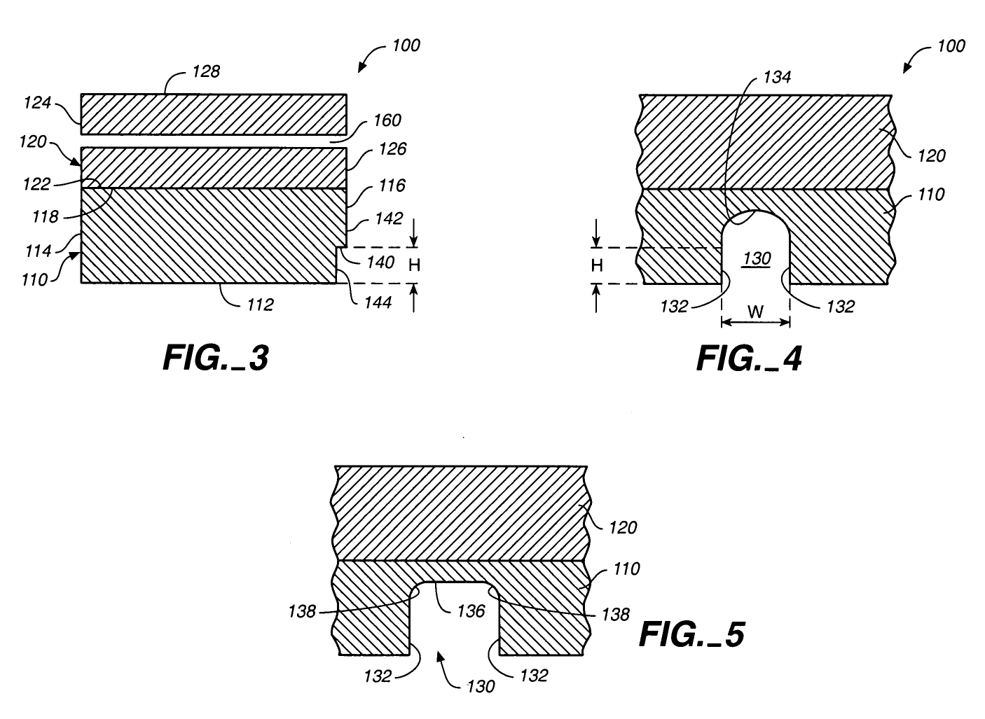

Referring to FIGS. 1 and 3, the retaining ring 100 can be constructed from two pieces, including a lower portion 110 and an upper portion 120. The lower portion 110 has a generally flat bottom surface 112, a cylindrical inner surface 114, a cylindrical outer surface 116, and a generally flat top surface 118. The inner surface 114 of the lower portion 110 forms a straight vertical cylindrical surface. In contrast, an overhanging portion 142 of the lower portion 110 has a larger outer diameter than the bottommost portion 144 of the lower portion, so that the outer surface 116 of the lower portion 110 includes a ledge 140.

The inner diameter of the inner surface 114 can be selected to constrain a 200 mm or 300 mm wafer. For example, in the former case, the inner diameter may be about 7.902 inches.

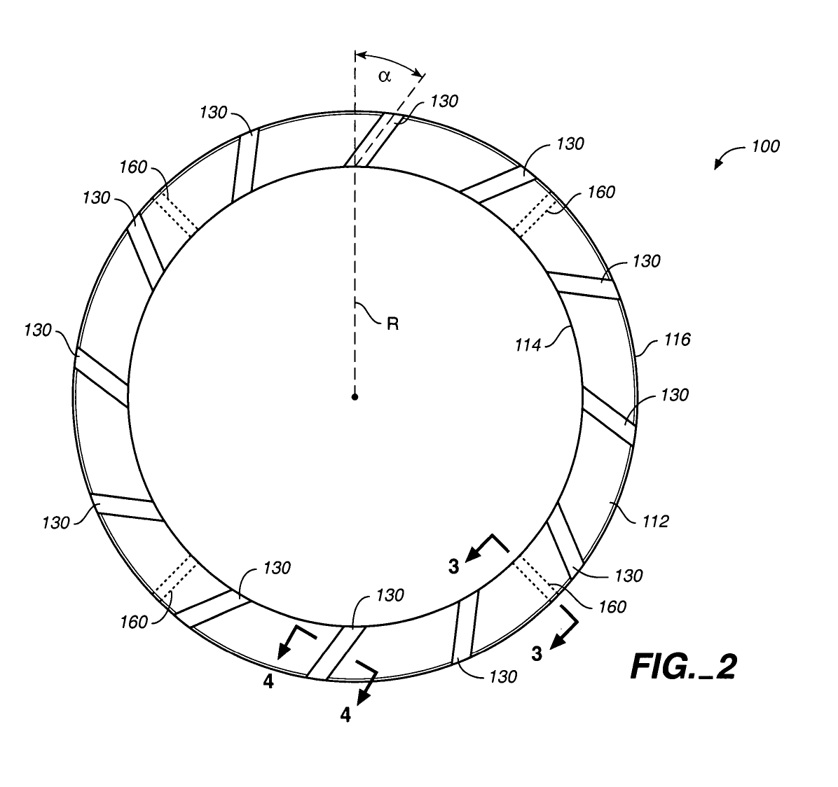

Referring to FIGS. 1 and 2, the bottom surface 112 of the lower portion 110 includes twelve channels or grooves 130 (there could be a different number of channels, such as eighteen channels) to permit a polishing fluid, such as slurry, which can include abrasives or be abrasive-free, to flow underneath the retaining ring to the substrate. The channels 130 can be generally straight, and extend from the inner surface 114 to the outer surface 116 of the retaining ring 100. Each channel 130 can have a width W (see FIG. 4) of about 0.030 to 1.0 inches, such as 0.125 inches.

The channels 130 on the bottom surface 112 can be distributed at equal angular intervals around the retaining ring 100. The channels are typically oriented at an angle α, such as 45°, relative to a radial segment (R) extending through the center of the retaining ring 100, but other angles of orientation, such as between 30° and 60°, are possible.

Referring to FIG. 4, each channel 130 includes two vertical sidewalls 132 and a rounded ceiling 134, so that the channel 130 lacks sharp inner corners. For example, the rounded ceiling 134 can have a semicircular cross-section with a diameter equal to the distance between the two sidewalls 132. As another example, shown in FIG. 5, the ceiling of the groove could have a generally horizontal flat section 136, and the curvature 138 could be located just the corners where the ceiling intersects the sidewalls.

Returning to FIGS. 2 and 3, the height H of the sidewalls 132 may match the height of the ledge 140, and can be about 0.030 to 0.30 inches. The sidewalls can have a uniform height across the length of the channel, so that the total depth of the channel 130 is the same at the inner surface 114 as at the outer surface 116.

The lower portion 110 of the retaining ring 100 can be formed from a material that is chemically inert to the CMP process and is softer than the material of the upper portion 120. The material should be sufficiently elastic that contact of the substrate edge against the retaining ring 100 does not cause the substrate to chip or crack. However, the retaining ring 100 should not be so elastic as to extrude into the substrate receiving recess when the carrier head puts a downward pressure on the retaining ring 100. The retaining ring 100 should also be durable and have a low wear rate, although it is acceptable for the retaining ring 100 to wear away. For example, the retaining ring 100 can be made of a plastic, such as polyphenylene sulfide (PPS), polyethylene terephthalate (PET), polyetheretherketone (PEEK), polybutylene terephthalate (PBT), polytetrafluoroethylene (PTFE), polybenzimidazole (PBI), polyetherimide (PEI), or a composite material.

Referring to FIGS. 1 and 3, the upper portion 120 has a generally flat bottom surface 122, a cylindrical inner surface 124, a cylindrical outer surface 126, and a generally flat top surface 128. The top surface 128 includes holes to receive mechanical fasteners, such as bolts, screws, or other hardware (such as screw sheaths or inserts) for securing the retaining ring 100 to the carrier head together (there could be a different number of holes). Additionally, the top surface 128 can have one or more alignment apertures positioned to mate to a corresponding pin on the carrier head to ensure proper alignment when the retaining ring 100 is secured to the carrier head.

The outer surface 126 of the upper portion 120 is generally vertical, and has the same outer diameter as the overhanging portion 142 of the lower portion 110. Similarly, the inner surface 124 of the upper portion 120 is generally vertical, and has the same inner diameter as the lower portion 110.

The upper portion 120 of the retaining ring 100 can include one or more passages 160, e.g., four drain holes spaced at equal angular intervals around the retaining ring, to provide pressure equalization, for injection of cleaning fluid, or expulsion of waste. These drain holes 160 extend horizontally through the upper portion 120 from the inner surface 124 to the outer surface 126. Alternatively, the drain holes can be tilted, e.g., higher at the inner diameter surface than at the outer diameter surface, or the retaining ring can be manufactured without drain holes.

The upper portion 120 can be formed from a rigid material, such as metal. Suitable metals for forming the upper portion include stainless steel, molybdenum, or aluminum. Alternatively, a ceramic can be used. The upper portion 120 can be more rigid than the lower portion 110.

The lower portion 110 and the upper portion 120 are connected at their top and bottom surfaces 118 and 122, respectively, to form the retaining ring 100. When the upper portion 110 and lower portion 120 are aligned and mated, the retaining ring 1 00 has a unitary surface The two parts can be joined using an adhesive, mechanical fasteners such as screws, or a press-fit configuration. The adhesive layer can be a two-part slow-curing epoxy, such as Magnobond-6375™, available from Magnolia Plastics of Chamblee, Ga.

When the retaining ring 100 is secured to a base of a carrier head, the circumference of the top of the outer diameter 180 can be substantially the same as the circumference of the base of the carrier head so that no gap exists along the outer edge of the carrier head.

Other implementations are possible. For example, various sections of the inner or outer surfaces 114, 116, 124 and 126 can have straight, sloped, or mixed straight and sloped geometry. Various other features, such as ledges or flanges, can be present on the upper surface 128 to permit the retaining ring to mate to the carrier head. The holes for screws or screw sheaths can be formed on the flange portion.

As another example, the retaining ring 100 can be constructed from a single piece of plastic, using, for example, PPS, instead of being formed from separate upper 145 and lower portions 105.

As another example, other types of channels are possible. The channels can be flared so that they are wider at the outer surface 116 than at the inner surface 115. The channels can be curved rather than straight. The channels can be deeper at the inner surface 114 than at the outer surface 116, or vice versa.

Although various positional descriptors, such as “top” and “bottom” are used, these terms are to be understood as relative to the polishing surface, as the retaining ring can be used in polishing systems in which the substrate is face up, face down, or in which the polishing surface is vertical.

The present invention has been described in terms of a number of embodiments. The invention, however, is not limited to the embodiments depicted and described. Rather, the scope of the invention is defined by the appended claims.

1. A retaining ring comprising:
a generally annular body having a top surface, a bottom surface, an inner diameter surface, and an outer diameter surface, wherein the bottom surface includes a plurality of channels, each channel extending from the inner diameter surface to the outer diameter surface and having a rounded ceiling.

2. The retaining ring of claim 1, wherein the rounded ceiling has a semi-circular cross-section.

3. The retaining ring of claim 2, wherein the semi-circular cross-section has a diameter about equal to a width of the channel.

4. The retaining ring of claim 1, wherein the rounded ceiling has a flat portion.

5. The retaining ring of claim 4, wherein the rounded ceiling is rounded at an intersection of the flat portion and vertical side-walls of the channel.

6. The retaining ring of claim 1, wherein each channel includes substantially vertical side-walls.

7. The retaining ring of claim 1, wherein the plurality of channels have substantially uniform depth.

8. The retaining ring of claim 1, wherein the plurality of channels are oriented at an angle relative to a radial segment extending through the center of the retaining ring.

9. The retaining ring of claim 8, wherein the angle is between 30° and 60°.

10. The retaining ring of claim 1, wherein the outer diameter surface includes a ledge.

11. The retaining ring of claim 10, wherein the outer diameter surface includes a first portion adjacent the bottom surface that has an outer diameter less than a second portion adjacent the top surface.

12. The retaining ring of claim 10, wherein the each channel includes substantially vertical side-walls, the side walls extending to substantially the same depth as the ledge.

13. The retaining ring of claim 1, wherein the annular body comprises a wearable material.

14. The retaining ring of claim 1, wherein the annular body comprises an upper portion and a lower portion, the upper portion being more rigid than the lower portion.

15. The retaining ring of claim 14, wherein the channels are formed in the lower portion.

16. The retaining ring of claim 15, wherein the lower portion is formed of a wearable material.

17. The retaining ring of claim 15, further comprising a plurality of passages extending through the upper portion from the inner diameter surface to the outer diameter surface.

18. The retaining ring of claim 1, wherein the plurality of channel are distributed at substantially equal angular intervals around the retaining ring.

19. A carrier head comprising:
a substrate receiving surface;
a generally annular retaining ring surrounding the substrate receiving surface, the retaining ring having a top surface, a bottom surface, an inner diameter surface, and an outer diameter surface, wherein the bottom surface includes a plurality of channels, each channel extending from the inner diameter surface to the outer diameter surface and having a rounded ceiling.

20. A method of polishing, comprising:
creating relative motion between a substrate and a polishing surface;
restraining the substrate with retaining ring that has a top surface, a bottom surface, an inner diameter surface, and an outer diameter surface, wherein the bottom surface includes a plurality of channels, each channel extending from the inner diameter surface to the outer diameter surface and having a rounded ceiling; and
supplying a polishing liquid to the polishing surface so that the polishing liquid flows through the channels and beneath the retaining ring to the substrate.
